(19) United States
(12) Patent Application Publication
(10) Pub. No.: US 2007/0062802 A1
(43) Pub. Date: Mar. 22, 2007

(54) System and method for managing a plasma process and method for manufacturing an electronic device

(76) Inventors: Katsuyuki Sekine, Yokohama-shi (JP); Shinji Mori, Yokohama-shi (JP); Takashi Shimizu, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/516,773

(22) Filed: Sep. 7, 2006

(30) Foreign Application Priority Data
Sep. 16, 2005 (JP) P2005-270267

(51) Int. Cl. H05F 3/00; C23C 14/00; C25B 11/00; C25B 13/00; C25B 9/00

(52) U.S. Cl. 204/164; 204/298.08

(57) ABSTRACT

A system for managing a plasma processing apparatus includes an impedance matching tool for matching impedance in a transmission line feeding a high frequency wave generating a plasma into a processing chamber; a collection unit collecting time series data of an adjustment parameter of the impedance matching tool; a reference creation module creating management reference data by reference time series data of the adjustment parameter, the reference time series data collected from a reference plasma process against a reference substrate; an initialization module initializing the adjustment parameter for a target plasma process against a target substrate; a recording module recording target time series data of the adjustment parameter adjusted so as to minimize a reflection wave of the high frequency wave in the target plasma process; and a determination module determining an abnormality of the target plasma process by comparing the target time series data with the management reference data.

### CROSS REFERENCE TO RELATED APPLICATIONS AND INCORPORATION BY REFERENCE

This application is based upon and claims the benefit of priority from prior Japanese Patent Application P2005-270267 filed on Sep. 16, 2006; the entire contents of which are incorporated by reference herein.

### BACKGROUND OF THE INVENTION

1. Field of the Invention

The present invention relates to a system and a method for managing a plasma process, and a method for manufacturing an electronic device by the plasma process.

2. Description of the Related Art

During the manufacturing process of an electronic device, such as a semiconductor device, a liquid crystal display (LCD) and the like, various plasma processes and plasma reactions are used for dry etching, surface modification, chemical vapor deposition (CVD), ion implantation, and the like. In the plasma process, a high frequency wave is fed to a discharge electrode, which is installed in a processing chamber of a plasma processing apparatus, from a high frequency power source. The high frequency wave discharges a gas introduced into the processing chamber so as to generate a plasma.

The state of the plasma is changed or determined by the type of gas, the pressure inside the processing chamber, the reaction product deposited on an inner wall of the processing chamber, and the like. Also, the state of the plasma may be changed even during plasma processing. In association with the change of the plasma state, the impedance of a plasma discharge is changed, and a reflection wave of the applied high frequency wave is increased so as to decrease the effective power of the plasma discharge. In order to efficiently carry out plasma processing, an impedance matching tool is usually installed for automatically adjusting the plasma discharge so that the reflective waves are minimized against an incident high frequency wave (refer to Japanese Patent No. 3107757 and Japanese Laid Open No. 2000-173982).

However, in plasma process for dry etching, surface modification, CVD, ion implantation, and the like, a method for easily examining whether a quality control (QC) characteristic, such as nitrogen concentration of a surface modifying layer, a CVD film thickness, resistivity of an implanted layer, which is determined in accordance with a performance requirement of the semiconductor device to be within a QC reference, is not provided. Under the existing circumstances, performance is determined by measuring plasma processed semiconductor wafers sampled at a sampling rate of one wafer per twenty-five wafers, for example, as to whether the QC characteristic is controlled within the QC reference.

In particular, in a single wafer processing apparatus, plasma process is carried out for each semiconductor substrate. Thus, even if the QC characteristic deviates from the QC reference, it is difficult to immediately detect the deviation of the QC characteristic. By measurement of performance after the completion of manufacturing of the semiconductor device, the deviation from the QC reference is detected, and thus significant losses of time and semiconductor substrates may occur. As a result, the manufacturing yield is decreased.

Moreover, when the QC characteristic of the plasma process deviates from the QC reference, maintenance of the plasma processing apparatus is executed. From a viewpoint of management of the plasma processing apparatus, a management method for executing maintenance, after a plasma processing result deviates from the QC reference, may not correspond to the planned maintenance. Thus, the operating rate of the plasma processing apparatus is decreased.

### SUMMARY OF THE INVENTION

A first aspect of the present invention inheres in a system for managing a plasma process including an impedance matching tool for matching impedance in a transmission line feeding a high frequency wave into a processing chamber, the high frequency wave generating a plasma in the processing chamber; a collection unit configured to collect time series data of an adjustment parameter of the impedance matching tool; a reference creation module configured to create management reference data by reference time series data of the adjustment parameter, the reference time series data collected from a reference plasma process against a reference substrate; an initialization module configured to initialize the adjustment parameter for a target plasma process against a target substrate; a recording module configured to record target time series data of the adjustment parameter adjusted so as to minimize a reflection wave of the high frequency wave in the target plasma process; and a determination module configured to determine an abnormality of the target plasma process by comparing the target time series data with the management reference data.

A second aspect of the present invention inheres in a method for managing a plasma process including creating management reference data by reference time series data of an adjustment parameter of an impedance matching in a transmission line feeding a high frequency wave to generate a plasma, the reference time series data collected during a reference plasma process against a reference substrate; starting a target plasma process against a target substrate by initializing the adjustment parameter; recording target time series data of the adjustment parameter adjusted so as to minimize a reflection wave of the high frequency wave in the target plasma process; and determining abnormality of the target plasma process by comparing the target time series data with the management reference data.

A third aspect of the present invention inheres in a method for manufacturing an electronic device including creating management reference data by reference time series data of an adjustment parameter of an impedance matching in a transmission line feeding a high frequency wave to generate a plasma, the reference time series data collected during a reference plasma process against a reference substrate; starting a target plasma process against a target substrate by initializing the adjustment parameter; recording target time series data of the adjustment parameter adjusted so as to minimize a reflection wave of the high frequency wave in the target plasma process; determining abnormality of the target plasma process by comparing the target time series data with the management reference data; and executing another plasma process against another target substrate, after executing maintenance of a plasma processing apparatus in which the plasma is generated, when the target plasma process is determined to be abnormal.

### BRIEF DESCRIPTION OF THE DRAWINGS

FIG. 1 is a schematic view showing an example of a configuration of a system for managing a plasma process according to a first embodiment of the present invention;

FIG. 2 is a cross sectional view showing an example of a semiconductor substrate to be processed by a plasma processing apparatus according to the first embodiment of the present invention;

FIG. 3 is a cross sectional view showing an example of the semiconductor substrate after a plasma process according to the first embodiment of the present invention;

FIG. 4 is a diagram showing an example of a relation of an adjustment parameter and a plasma processing time used in a method for managing the plasma process according to the first embodiment of the present invention;

FIG. 5 is a diagram showing another example of a relation of an adjustment parameter and a plasma processing time used in the method for managing the plasma process according to the first embodiment of the present invention;

FIG. 6 is a diagram showing an example of a management range of the adjustment parameter used in the method for managing the plasma process according to the first embodiment of the present invention;

FIG. 7 is a diagram showing another example of a management range of the adjustment parameter used in the method for managing the plasma process according to the first embodiment of the present invention;

FIG. 8 is a diagram showing an example of a monitor curve of the adjustment parameter used in the method for managing the plasma process according to the first embodiment of the present invention;

FIG. 9 is a diagram showing another example of the monitor curve of the adjustment parameter used in the method for managing the plasma process according to the first embodiment of the present invention;

FIG. 10 is a flowchart showing an example of the method for managing the plasma process according to the first embodiment of the present invention;

FIG. 11 is a schematic view showing an example of a configuration of a system for managing a plasma process according to a second embodiment of the present invention;

FIG. 12 is a diagram showing an example of a relation of an adjustment parameter and a number of substrate used in a method for managing a plasma process according to the second embodiment of the present invention; and

FIG. 13 is a flowchart showing an example of the method for managing the plasma process according to the second embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

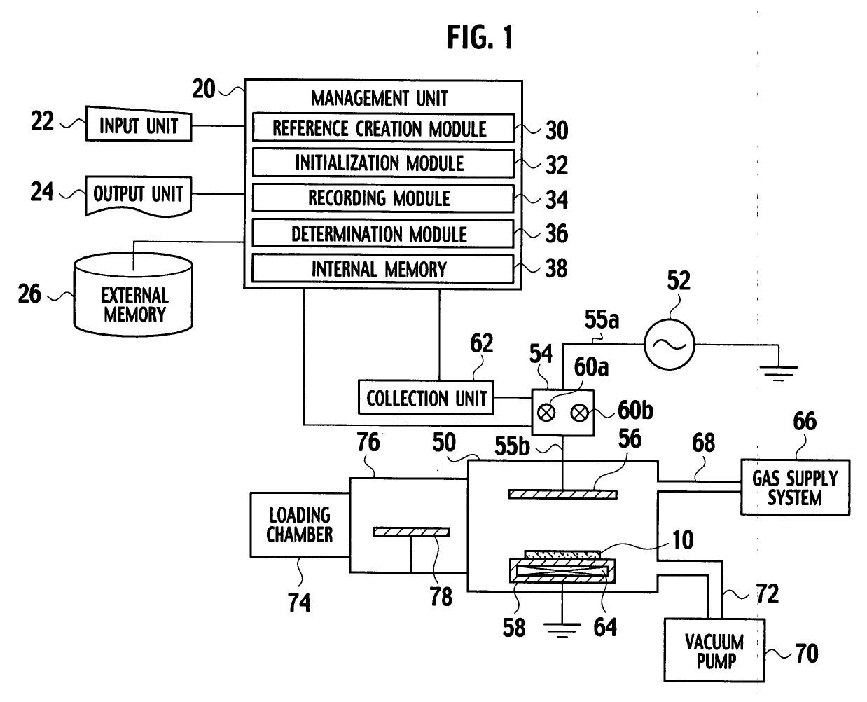

A management system according to a first embodiment of the present invention includes a collection unit 62, a management unit 20 and the like, which are connected to a plasma processing apparatus, as shown in FIG. 1. The plasma processing apparatus includes a processing chamber 50, a high frequency power source 52, an impedance matching tool 54, a gas supply system 66, a vacuum pump 70 and the like.

The grounded high frequency power source 52 is connected through a transmission line 55a to the impedance matching tool 54. The impedance matching tool 54, having a first movable part 60a and a second movable part 60b, is connected through a transmission line 55b to a discharge electrode 56 inside the processing chamber 50. A substrate stage 58 serving another discharge electrode on which a substrate 10 is loaded is arranged so as to face the discharge electrode 56 to which the high frequency wave is supplied. A heating source 64 is installed in the substrate stage 58. The substrate stage 58 is grounded.

The gas supply system 66 is connected through a gas supply piping 68 to the processing chamber 50. The vacuum pump 70 is connected through an exhaust piping 72 to the processing chamber 50. Also, a transfer chamber 76, having a loading robot 78, is connected to the processing chamber 50. A loading chamber 74 is connected to the transfer chamber 76.

The management unit 20 is connected to the impedance matching tool 54 and the collection unit 62. An input unit 22, an output unit 24, an external memory 26 and the like are connected to the management unit 20. The management unit 20 includes a reference creation module 30, an initialization module 32, a recording module 34, a determination module 36, an internal memory 38 and the like.

The high frequency wave generated in the high frequency power source 52 is transmitted through the transmission line 55a, the impedance matching tool 54 and the transmission line 55b to the discharge electrode 56 in the processing chamber 50 of the plasma processing apparatus, to generate a plasma. Positions of the first and second movable parts 60a, 60b of the impedance matching tool 54 are automatically adjusted such that the reflection waves against the incident high frequency wave are minimized. The positions of the first and second movable parts 60a, 60b are used as adjustment parameters for impedance matching.

For example, for the high frequency power source 52, a microwave oscillator with an oscillation frequency of about 2.45 GHz or the like is used. For each of the transmission lines 55a, 55b, a waveguide or the like is used. Also, for the impedance matching tool 54, a stub tuner or the like is used. For the first and second movable parts 60a, 60b of the impedance matching tool 54, dual-axis matching stubs are used.

In addition, the oscillation frequency of the high frequency power source 52 is not so limited as described above. For example, an oscillation frequency in a range of about 10 MHz to the GHz band may be used. For the transmission lines 55a, 55b, a high frequency transmission line such as a coaxial cable, a micro strip line or the like may be used. Also, the impedance matching tool 54 is not limited to the stub tuner. For example, an EH tuner having two matching plungers may be used. Also, a variable condenser may be used for the impedance matching tool 54. When using an EH tuner or a variable condenser, as an adjustment parameter, a position of each plunger or each condenser electrode is used. When each of the stubs, the plungers, or the condenser electrodes is controlled by a drive voltage, the drive voltage may be used as the adjustment parameter. Moreover, the movable parts of the impedance matching tool 54 are not limited to the first and second movable parts 60a, 60b. The movable part may be a single movable part or three or more movable parts.

The vacuum pump 70 evacuates the processing chamber 50 through the exhaust piping 72. The gas supply system 66 supplies various gases used for plasma process, through the gas supply piping 68 to the evacuated processing chamber 50. Plasma process is used for dry etching, surface modification, CVD, sputtering, ion implantation, and the like. For surface modification, a gas, such as nitrogen (N₂), oxygen (O₂), nitric oxide (NO), nitrous oxide (N₂O), argon (Ar) and the like, may be used. Also, for CVD and the like, a gas, such as monosilane (SiH₄), disilane (Si₂H₆), dichlorosilane (SiH₂Cl₂), organic silane, O₂, N₂, NO, ammonia (NH₃), and the like, may be used. For etching, a gas, such as halogen, halogen compound, hydrogen (H₂), helium (He), O₂, N₂, Ar, and the like, may be used. For an ion source of ion implantation, a gas such as diborane (B₂H₆), arsine (AsH₃), phosphine (PH₃) and the like, may be used.

The collection unit 62 collects time series data, such as the positions, which are used for the adjustment parameters, of the first and second movable parts 60a, 60b of the impedance matching tool 54 and the like. For example, the high frequency wave is applied to the process gas supplied in the processing chamber 50, which is evacuated before the process gas is introduced, so as to excite plasma discharge. During the plasma discharge, each position of the first and second movable parts 60a, 60b is automatically adjusted so as to minimize a reflection wave of the high frequency wave. Each position of the first and second movable parts 60a, 60b is monitored at a predetermined sampling time. The monitored values of the positions of the first and second movable parts 60a, 60b are collected as the time series data by the collection unit 62.

The reference creation module 30 of the management unit 20 creates management reference data from reference time series data of the adjustment parameters collected by a reference plasma process against a reference substrate using the plasma processing apparatus. The initialization module 32 initializes the adjustment parameter to an initial value in a target plasma process against a target substrate by the plasma processing apparatus. The recording module 34 records target time series data of the adjustment parameters which are adjusted such that the reflection wave of the high frequency wave are minimized. The determination module 36 compares the target time series data with the management reference data and determines any abnormality of the plasma processing apparatus.

The management unit 20 and the collection unit 62 may be part of a central processing unit (CPU) of a general purpose computer system. The reference creation module 30, the initialization module 32, the recording module 34, and the determination module 36 may be discrete hardware, or may be provided by virtually equivalent functions achieved by software, using the CPU of the general purpose computer system.

The external memory 26 stores the management reference data, the initial values of the adjustment parameters, the time series data of the adjustment parameters, and the like. The external memory 26 may be an external storage device, such as a semiconductor memory, such as a semiconductor ROM, and a semiconductor RAM, a magnetic disc device, a magnetic drum device, a magnetic tape device, and the like, or may be provided by a main memory unit in the CPU.

The input unit 22 refers to devices, such as a keyboard and a mouse. When an input operation is performed from the input unit 22, corresponding key information is transmitted to the management unit 20. The output unit 24 refers to a screen monitor, such as a liquid crystal display (LCD), a light emitting diode (LED) panel, an electroluminescent (EL) panel and the like. The output unit 24 displays the data recorded by the management unit 20, the determination results acquired by the same, and the like.

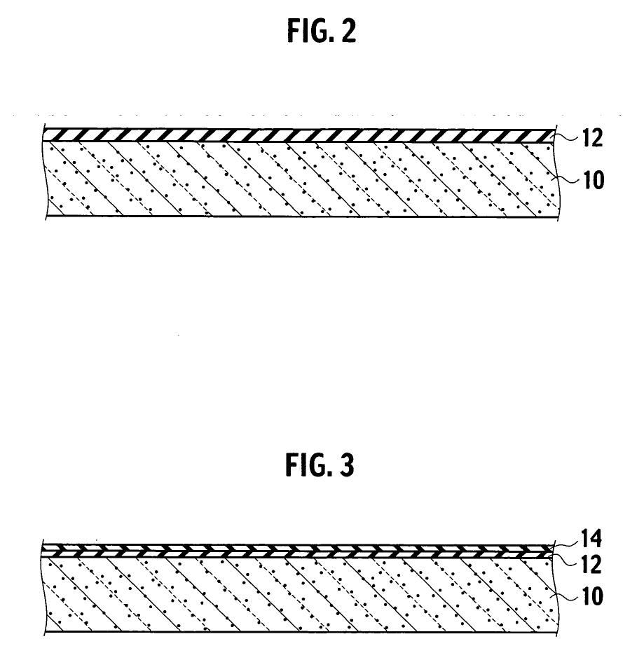

The first embodiment of the present invention will be described by exemplifying the plasma processing apparatus for surface modification of an insulating film, such as a silicon oxide (SiO₂) film and the like. As shown in FIG. 2, the substrate 10, such as a silicon (Si) substrate, in which a SiO₂ film 12 having a thickness of about 2 nm is formed on a surface by thermal oxidation, is loaded into the loading chamber 74. The substrate 10 is transferred by the loading robot 78 from the loading chamber 74 to the processing chamber through the transfer chamber 76, to be loaded on the substrate stage 58 of the processing chamber 50.

The processing chamber 50 is evacuated to a predetermined pressure by the vacuum pump 70. For example, a mixture gas of Ar and N₂ is introduced into the processing chamber 50. The pressure inside the processing chamber 50 is set to about 70 mPa, and a wait period elapses until the pressure at about 70 mPa become stable. The substrate 10 is heated to about 40° C. by the heating source 64 that is provided in the substrate stage 58.

Before exciting a plasma, the positions of the first and second movable parts 60a, 60b of the impedance matching tool 54, which are the adjustment parameters, are shifted to the initial positions as a reference. The initial positions may be any positions. It is desirable for stable plasma excitation to select the combination of positions of the first and second movable parts 60a, 60b where the plasma is most easily excited.

Immediately after the first and second movable parts 60a, 60b are shifted to the initial positions, the positions of the first and second movable parts 60a, 60b are collected, for example, for about every 500 milliseconds. After that, a microwave at a frequency of about 2.45 GHz with a high frequency power of about 700 W is introduced into the processing chamber 50 so as to excite the plasma. The positions of the first and second movable parts 60a, 60b are adjusted such that the reflection waves of the microwave are always minimized.

After continuing the plasma excitation for about 30 seconds, supply of the microwave is stopped to stop the plasma excitation. Thus, as shown in FIG. 3, the surface of the SiO₂ film 12 is modified so as to form a silicon oxynitride (SiON) film 14 on top of the surface of the SiO₂ film 12. In order to determine success or failure of the surface modification, a QC characteristic, such as film thickness, refractive index, nitrogen mole fraction and the like, is measured for the formed SiON film 14 by ellipsometry, X-ray photoelectron spectroscopy (XPS), and the like. If the QC characteristic is controlled within a QC reference, the plasma process is determined as a success. If the QC characteristic deviates from the QC reference, the plasma process is determined as a failure.

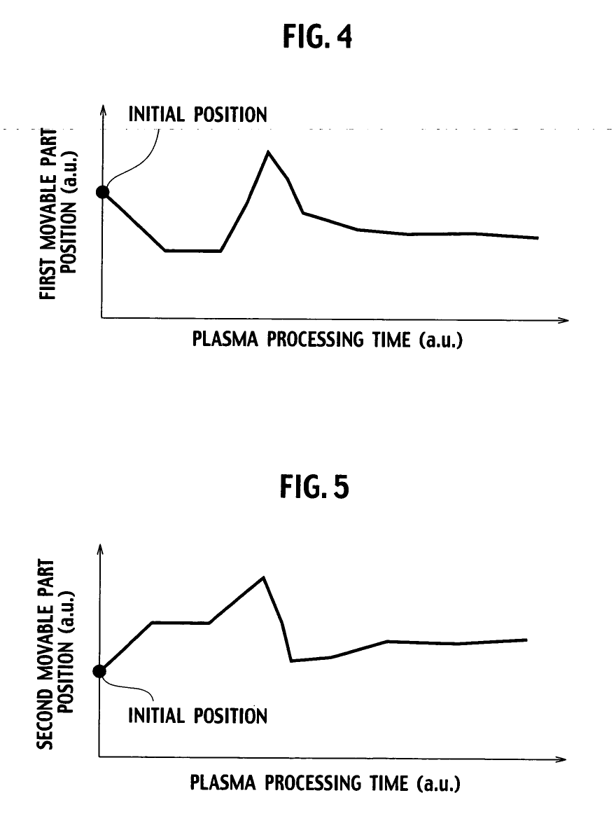

Using a reference substrate as the substrate 10, the recording module 34 of the management unit 20 records the positions of the first and second movable parts 60a, 60b, collected by the collection unit 62, as the time series data with respect to the plasma processing time. As a result, as shown in FIGS. 4, 5, curves of the positions of the first and second movable parts 60a, 60b are obtained with respect to the plasma processing time. The curves of the positions of the first and second movable parts 60a, 60b with respect to the plasma processing times can be repeatedly obtained, when the initial positions of the first and second movable parts 60a, 60b and the plasma processing conditions are the same and the plasma processing result is normal.

Even though the plasma processing result is successful, when there is no reproducibility in the time series data of the positions of the first and second movable parts 60a, 60b with the same plasma processing condition, the initial positions as the reference positions are adjusted. In this way, the reproducibility of the time series data of the positions of the first and second movable parts 60a, 60b can be achieved.

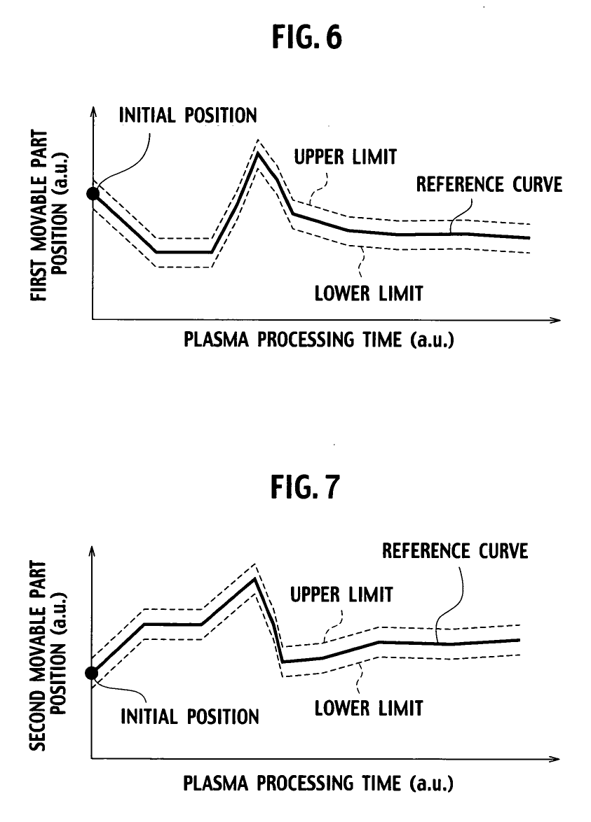

The reference creation module 30 creates a relation between each position of the first and second movable parts 60a, 60b and the plasma processing time as a reference curve for each plasma processing condition, when the plasma processing result is normal. As shown in FIGS. 6, 7, management reference data is created by providing a management range for the reference curve. As the management range, for example, an upper limit and a lower limit are provided at +5% of the positions of the first and second movable parts 60a, 60b for each plasma processing time. The management reference data is stored in the external memory 26.

Next, using a target substrate as the substrate 10, the surface modification by “a target plasma process” is carried out by use of the plasma processing apparatus. The initialization module 32 transmits the initial positions of the first and second movable parts 60a, 60b of the reference curves, to the impedance matching tool 54. The collection unit 62 collects the positions of the first and second movable parts 60a, 60b. The recording module 34 records the collected positions of the first and second movable parts 60a, 60b as the target time series data with respect to the plasma processing time. Before the next surface modification is carried out, monitor curves of the recorded target time series data are created. The determination module 36 compares the created monitor curves with the management reference data.

For example, when the monitor curves are within the range of the upper and lower limits of the management reference data, the target plasma process is determined to be a success by the determination module 36. The determined result is displayed on the output unit 24 and reported to a controller (not shown) of the plasma processing apparatus or an operator. Subsequently, the next target substrate is similarly processed by use of the plasma processing apparatus.

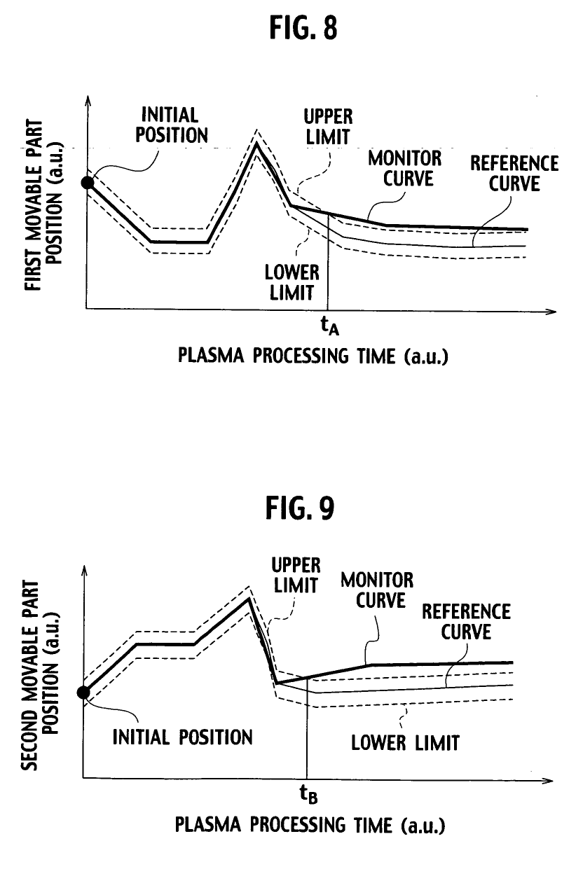

Additionally, as shown in FIGS. 8, 9, when the monitor curves of the positions of the first and second movable parts 60a, 60b deviate from the upper limit of the management reference data at plasma processing times t_{A}, t_{B}, the target plasma process is determined to be a failure by the determination module 36. As a result, the plasma processing apparatus is determined to be abnormal, and the target plasma process for the next target substrate is canceled. Also, maintenance of the plasma processing apparatus is executed.

In addition, even when any one of the monitor curves of the positions of the first and second movable parts 60a, 60b deviate from the upper or lower limit of the management reference data, the plasma processing apparatus is determined to be abnormal. Also, even when the monitor curves of the positions of the first and second movable parts 60a, 60b deviate for a moment from the upper or lower limit of the management reference data, the plasma processing apparatus is determined to be abnormal.

In the management system according to the first embodiment of the present invention, it is possible to immediately determine success or failure of each of the target plasma processes. When the target plasma process fails, it is possible to cancel the next target plasma process and to execute maintenance of the plasma processing apparatus. As a result, it is possible to decrease losses of time and the target substrates, and to suppress decrease of the manufacturing yield. Also, it is possible to promptly determine maintenance timing of the plasma processing apparatus.

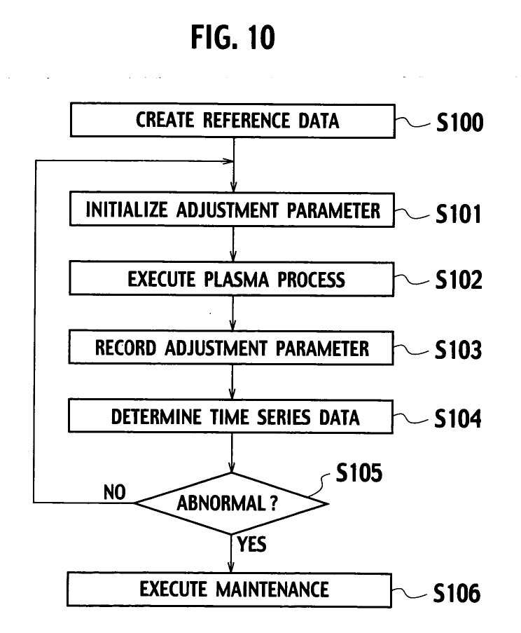

A management method according to the first embodiment of the present invention will be described with reference to the flowchart shown in FIG. 10.

In Step S100, a reference substrate is processed by a reference plasma process using the plasma processing apparatus. The collection unit 62 collects reference time series data of adjustment parameters of the first and second movable parts 60a, 60b of the impedance matching tool 54 to be adjusted so as to minimize a reflection wave of the high frequency wave for generating the plasma. The reference creation module 30 of the management unit 20 provides a predetermined management range for the collected reference time series data and creates management reference data.

In Step S101, the initialization module 32 sends initial values of the adjustment parameters in the reference time series data to the impedance matching tool 54. The adjustment parameters of the first and second movable parts 60a, 60b are set to the initial values.

In Step S102, a target plasma process against a target substrate is started by use of the plasma processing apparatus.

In Step S103, the collection unit 62 collects target time series data of the adjustment parameters to be adjusted so as to minimize the reflection wave of the high frequency wave. The recording module 34 records the collected target time series data.

In Step S104, the determination module 36 compares the target time series data with the management reference data and determines success or failure of the target plasma process. In Step S105, when the target plasma process is successful, the plasma processing apparatus is determined to be normal, and the process returns to Step S101 to carry out a next target plasma process.

In Step S105, when the target plasma process is a failure, the plasma processing apparatus is determined to be abnormal and the process advances to Step S106. In Step S106, maintenance of the plasma processing apparatus is executed.

In the management method according to the first embodiment of the present invention, success or failure of each of the target plasma processes is immediately determined. When the target plasma process has failed, it is possible to cancel the next target plasma process and then execute maintenance of the plasma processing apparatus. As a result, it is possible to decrease losses of time and the target substrates and to suppress a decrease in the manufacturing yield. Also, it is possible to promptly determine the maintenance timing of the plasma processing apparatus.

Additionally, after the maintenance of the plasma processing apparatus, the management reference data can be used to determine whether the maintenance is successful and if the plasma processing apparatus has recovered to normal operating state. For example, after the completion of the maintenance and by use of a test substrate, a test plasma process for surface modification is carried out to record time series data of the adjustment parameters. When the recorded time series data is within the management range of the management reference data, the maintenance is determined to be successful, and the plasma processing apparatus is determined to be recovered to a normal operating state. When the recorded time series data exceeds the management range of the management reference data, the maintenance is determined to be a failure. Thus, in the management method according to the first embodiment of the present invention, it is possible to easily determine the state of the plasma processing apparatus after the maintenance. Therefore, it is possible to greatly improve the operating rate of the plasma processing apparatus.

### Second Embodiment

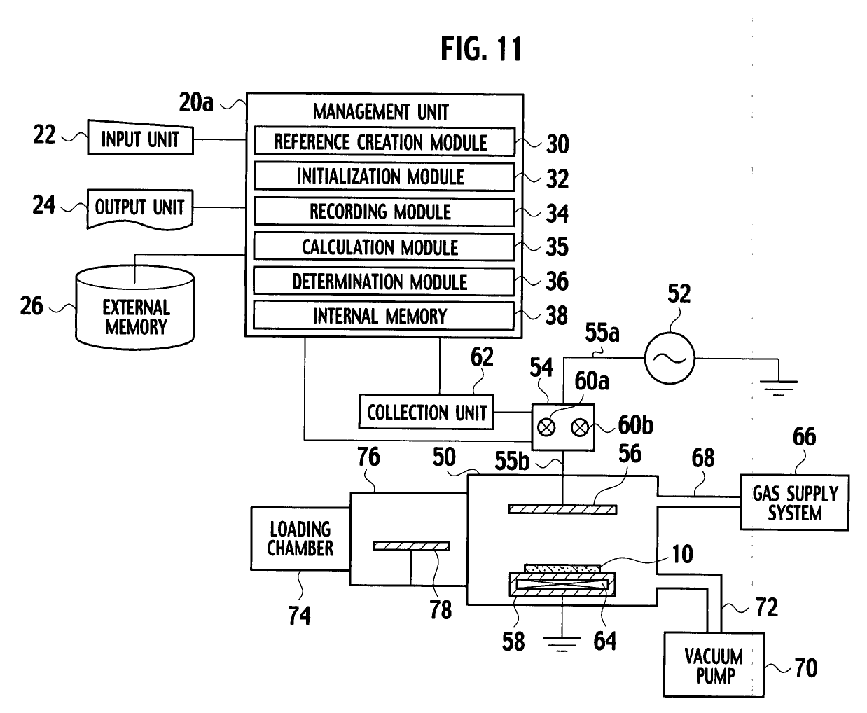

A management system according to a second embodiment of the present invention includes the collection unit 62, a management unit 20a connected to the impedance matching tool 54, as shown in FIG. 11. The management unit 20a includes the reference creation module 30, the initialization module 32, the recording module 34, a calculation module 35, the determination module 36, the internal memory 38, and the like. The input unit 22, the output unit 24, the external memory 26, and the like are connected to the management unit 20a.

The management system according to the second embodiment of the present invention differs from the first embodiment in that the management unit 20a includes the calculation module 35. The other configurations are similar to the first embodiment. Thus, duplicated descriptions are omitted.

The calculation module 35 of the management unit 20a calculates a change rate of the time series data of the adjustment parameters with respect to a number of substrates processed by plasma process. Based on the change rate, the determination module 36 predicts an expected number of substrates to be processed by the plasma process where the time series data of the adjustment parameters exceeds the upper or lower limit of the management reference data.

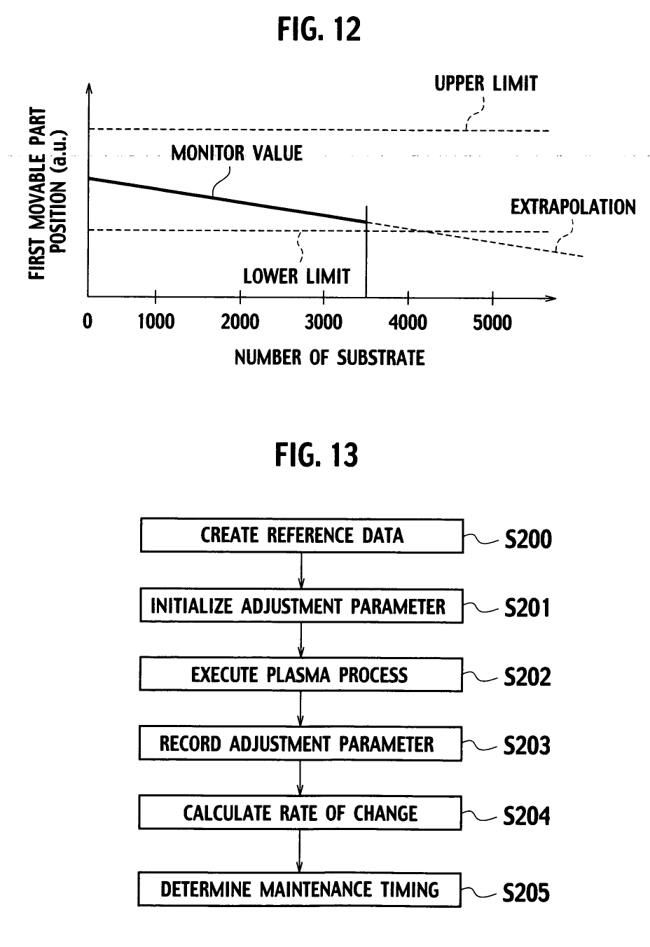

For example, a monitor value of the adjustment parameter at about 20 seconds after the plasma excitation is extracted from the time series data of the adjustment parameters. As shown in FIG. 12, when the number of substrates processed by the plasma processes is about 3500, a change rate of the monitor value of the position of the first movable part 60a is calculated by an approximated curve of the monitor values. The calculated change rate is used to extrapolate the approximation curve of the monitor value to estimate a change of the monitor value over the number of about 3500 substrates. As a result, it can be predicted that the monitor value will exceed the lower limit of the management reference data after the plasma processes of about additional 500 substrates. Thus, it is determined that the plasma processing apparatus will be abnormal after the plasma processes of about additional 500 substrates and maintenance of the plasma processing apparatus is required before processing of about additional 500 substrates.

In the management system according to the second embodiment of the present invention, it is possible to predict the expected number of substrates where the plasma processing apparatus will be abnormal and a maintenance timing of the plasma processing apparatus by recording and analyzing the time series data of the adjustment parameters with regard to the number of processed substrates. Thus, it is possible to improve the operating rate of the plasma processing apparatus.

A management method according to the second embodiment of the present invention will be described with reference to the flowchart shown in FIG. 13.

In Step S200, a reference substrate is processed by a reference plasma process using the plasma processing apparatus. The collection unit 62 collects reference time series data of adjustment parameters of the first and second movable parts 60a, 60b of the impedance matching tool 54, which are adjusted so as to minimize a reflection wave of the high frequency wave for generating the plasma. The reference creation module 30 of the management unit 20 provides a predetermined management range for the collected reference time series data and creates management reference data.

In Step S201, the initialization module 32 sends initial values of the adjustment parameters in the reference time series data to the impedance matching tool 54. The adjustment parameters of the first and second movable parts 60a, 60b are set to the initial values.

In Step S202, a target plasma process against a target substrate is started by use of the plasma processing apparatus.

In Step S203, the collection unit 62 collects target time series data of the adjustment parameters to be adjusted so as to minimize the reflection wave of the high frequency wave for the target plasma process. The recording module 34 records the collected target time series data.

In Step S204, the calculation module 35 calculates a change rate of the target time series data with respect to the number of target substrates processed by the plasma processing apparatus.

In Step S205, the determination module 36 predicts a change of the target time series data by the change rate of the target time series data and determines a maintenance timing based on an expected number of target substrates to exceed the management reference data.

In the management method according to the second embodiment of the present invention, the expected number of target substrates at which the plasma processing apparatus will be abnormal is predicted by recording and analyzing the time series data of the adjustment parameters with regard to the number of processed target substrates. Thus, it is possible to determine the maintenance timing of the plasma processing apparatus. Therefore, it is possible to improve the operating rate of the plasma processing apparatus.

### Other Embodiments

In the first and second embodiments of the present invention, surface modification, which introduces nitrogen into the surface of the SiO₂ film, using a plasma, is explained as plasma process. However, plasma process is not limited to surface modification processes. For example, plasma processing, such as deposition including sputtering and CVD, dry etching, ashing, and ion generation of ion implantation, is within the scope of the invention.

Further, in the first and second embodiments of the present invention, a manufacturing method for a semiconductor device is described. However, it should be easily understood from the foregoing descriptions that the present invention can also be applied to manufacturing methods for liquid crystal displays, magnetic recording devices and read heads thereof, surface acoustic wave devices, and the like.

Various modifications will become possible for those skilled in the art after storing the teachings of the present disclosure without departing from the scope thereof.

What is claimed is:

1. A system for managing a plasma process, comprising:
an impedance matching tool for matching impedance in a transmission line feeding a high frequency wave into a processing chamber, the high frequency wave generating a plasma in the processing chamber;
a collection unit configured to collect time series data of an adjustment parameter of the impedance matching tool;
a reference creation module configured to create management reference data by reference time series data of the adjustment parameter, the reference time series data collected from a reference plasma process against a reference substrate;
an initialization module configured to initialize the adjustment parameter for a target plasma process against a target substrate;
a recording module configured to record target time series data of the adjustment parameter adjusted so as to minimize a reflection wave of the high frequency wave in the target plasma process; and
a determination module configured to determine an abnormality of the target plasma process by comparing the target time series data with the management reference data.

2. The system of claim 1, further comprising:
a calculation module configured to calculate a change rate of the target time series data with respect to the number of target substrates processed by the plasma process.

3. The system of claim 1, wherein the adjustment parameter is a position of a movable part of the impedance matching tool.

4. The system of claim 1, wherein the impedance matching tool includes a plurality of movable part to adjust positions thereof so as to minimize the reflection wave.

5. The system of claim 1, wherein the management reference data provides a management range to the adjustment parameter of the reference time series data.

6. The system of claim 1, wherein the management reference data is created from the reference plasma process to determine that a quality control characteristic of the target plasma process is within a quality control reference range.

7. The system of claim 2, wherein the determination module predicts an expected number of the target substrates that can be processed before the target plasma process will perform abnormal processing.

8. A method for managing a plasma process, comprising:
creating management reference data by reference time series data of an adjustment parameter of an impedance matching in a transmission line feeding a high frequency wave to generate a plasma, the reference time series data collected during a reference plasma process against a reference substrate;
starting a target plasma process against a target substrate by initializing the adjustment parameter;
recording target time series data of the adjustment parameter adjusted so as to minimize a reflection wave of the high frequency wave in the target plasma process; and
determining abnormality of the target plasma process by comparing the target time series data with the management reference data.

9. The method of claim 8, further comprising:
executing maintenance of a plasma processing apparatus in which the plasma is generated, when the target plasma process is determined to be abnormal.

10. The method of claim 8, further comprising:
calculating a change rate of the target time series data with respect to the number of target substrates processed by the plasma process; and
determining maintenance timing of a plasma processing apparatus for performing the target plasma process based on the management reference data and the change rate.

11. The method of claim 8, wherein the adjustment parameter is a position of a movable part of an impedance matching tool configured to execute the impedance matching.

12. The method of claim 8, wherein the adjustment parameter is each position of a plurality of movable parts of an impedance matching tool configured to execute the impedance matching.

13. The method of claim 8, wherein the management reference data provides a management range to the adjustment parameter of the reference time series data.

14. The method of claim 8, wherein the management reference data is created from the reference plasma process to determine that a quality control characteristic of the target plasma process is within a quality control reference range.

15. A method for manufacturing an electronic device, comprising:
creating management reference data by reference time series data of an adjustment parameter of an impedance matching in a transmission line feeding a high frequency wave to generate a plasma, the reference time series data collected during a reference plasma process against a reference substrate;
starting a target plasma process against a target substrate by initializing the adjustment parameter;
recording target time series data of the adjustment parameter adjusted so as to minimize a reflection wave of the high frequency wave in the target plasma process;
determining abnormality of the target plasma process by comparing the target time series data with the management reference data; and
executing another plasma process against another target substrate, after executing maintenance of a plasma processing apparatus in which the plasma is generated, when the target plasma process is determined to be abnormal.

16. The method of claim 15, further comprising:
calculating a change rate of the target time series data with respect to the number of target substrates processed by the target plasma process; and
determining maintenance timing of the plasma processing apparatus based on the management reference data and the change rate.

17. The method of claim 15, wherein the adjustment parameter is a position of a movable part of an impedance matching tool configured to execute the impedance matching.

18. The method of claim 17, wherein the adjustment parameter is each position of a plurality of movable parts of an impedance matching tool configured to execute the impedance matching.

19. The method of claim 17, wherein the management reference data provides a management range to the adjustment parameter of the reference time series data.

20. The method of claim 17, wherein the management reference data is created from the reference plasma process to determine that a quality control characteristic of the target plasma process is within a quality control reference range.
